(19) United States
(12) Patent Application Publication
(10) Pub. No.: US 2006/0197120 A1
(43) Pub. Date: Sep. 7, 2006

(54) Gate electrode for semiconductor devices

(75) Inventors: Radu Catalin Surdeanu, Leuven (BE); Peter Adriaan Stolk, Bernin (FR)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILLIPS ELECTONICS N.C.

(21) Appl. No.: 10/550,741

(22) PCT Filed: Mar. 23, 2004
(86) PCT No.: PCT/IB04/50321

§ 371 Date: Sep. 22, 2005

(30) Foreign Application Priority Data
Mar. 28, 2003 (EP) 03100822.0

(51) Int. Cl. H01L 29/76

(52) U.S. Cl. 257/288

(57) ABSTRACT

The present invention provides an MIS type semiconductor device, comprising a semiconductor substrate and a gate electrode formed on the gate insulating film and formed of gate material. The gate electrode comprises: a first layer of activated crystalline gate material having a first side oriented towards a substrate and a second side oriented away from the substrate, the first layer of activated crystalline gate material having a doping level of 10¹⁹ ions/cm³ or higher, and a second layer of gate material at the second side of the first layer of activated crystalline gate material. The present invention also provides a method for making such a device.

The present invention relates to the field of semiconductor processing. In particular it relates to the fabrication of semiconductor devices having a gate, such as Metal-Insulator-Semiconductor (MIS) or Metal-Oxide-Semiconductor (MOS) transistor devices for example.

The scaling of semiconductor devices, in particular of MIS or MOS transistor devices has recently reached a stage where the length of a gate electrode is about few tens of nanometers.

Ion implantation is widely used in semiconductor processing, e.g. to dope gate material such as silicon, for example for making shallow junction or ultra-shallow junction devices. Ion implantation causes damage in the silicon lattice, and this damage has to be repaired by annealing in order to activate the dopants and to recover carrier mobility in the silicon. Post-implantation annealing is often carried out at a high temperature, for example between about 800° C. and 1000° C., for a time period of 30 minutes. Alternatively, rapid thermal annealing can be carried out, at still higher temperatures, for example at a temperature of 1100° C., during a shorter time period, for example for one second only.

In heavily-doped silicon, such as silicon having a dopant concentration of 10²⁰ ions/cm³ or more, the above annealing procedures are not capable of achieving complete activation of the dopants, one of the most important issues for improving transistor performance. Raising the temperature to provide higher temperature annealing during a same time period is a possible solution for obtaining better activation of the dopants. However, these higher temperatures also broaden the junctions which have been formed, and this is unacceptable in case of small devices.

This problem is solved in U.S. Pat. No. 5,882,953, in which a method of activating dopants in semiconductor material is described. The method comprises the steps of supersaturating the semiconductor material with a dopant, and applying a high density current to the supersaturated semiconductor material above a predetermined activation threshold. This method, however, cannot easily be integrated in e.g. existing CMOS processes.

In order to obtain the desired activation of ion implanted dopants in the gate, up to now not only annealing was used but also proper tuning of the grain size in the polysilicon gate. This resulted in a fine-grained polysilicon structure, suitable for diffusion of dopants towards the polysilicon-insulator interface during the activation anneal step. However, the optimal grain size is about 30 nm, which means in the recent advanced, smaller technologies basically that the gate electrode comprises only a few grains.

Mainly two problems arise at this point. In the first place, gaps between the gate material and the gate insulator appear during gate formation, e.g. during polysilicon formation, thus increasing the so-called “equivalent oxide thickness” (EOT), and thus decreasing the ON-current, therefore degrading the transistor performance. In the second place, gate activation at levels of approximately 10²⁰ ions/cm³ becomes a real challenge, since in the advanced technologies there has to be dealt with diffusion in crystalline silicon (one grain only) and not through grain boundaries.

It is an object of the present invention to provide a method of satisfactory dopant activation in highly-doped semiconductor material forming for example a gate, and to provide devices incorporating such highly-doped activated semiconductor material.

The above objective is accomplished by a method and device according to the present invention.

The present invention provides a method of forming a semiconductor device having a gate, comprising:
providing a first layer of amorphous gate material,
doping the first layer of amorphous gate material, thus forming a doped first layer of amorphous gate material,
thermally activating the doped first layer of gate material, thus forming an activated first layer of gate material, and
providing a second layer of gate material on top of the activated first layer of gate material.

This way, a highly activated gate electrode can be obtained, even for advanced technologies where the gate electrode comprises only a few grains of gate material.

Providing a first layer of amorphous gate material may include forming a layer of amorphous gate material having a thickness of about 10 nm to 40 nm, preferably about 20 nm to 30 nm.

Providing a second layer of gate material may include forming a layer of gate material having a thickness of about 50 nm to 150 nm, preferably about 70 nm to 130 nm.

The second layer of gate material may comprise amorphous gate material or polycrystalline gate material.

The first and second layers of gate material may be silicon-based. Silicon is material commonly used for semiconductor products. In that case, the first layer is amorphous silicon, which is cheap and easy to manufacture and the second layer is amorphous silicon or polysilicon.

The doping may be done with n-type impurities for making NMOS devices or with p-type impurities for making PMOS devices.

A method according to the present invention may further comprise patterning the second layer of gate material and the activated first layer of gate material to form one or more gates on the substrate.

The present invention also provides an MIS type semiconductor device, comprising a semiconductor substrate and a gate electrode formed on the gate insulating film and formed of gate material.

The gate electrode comprises:
a first layer of activated crystalline gate material having a first side oriented towards a substrate and a second side oriented away from the substrate, the first layer of activated crystalline gate material having a doping level of 10¹⁹ ions/cm³ or higher, and
a second layer of gate material at the second side of the first layer of activated crystalline gate material.

The first layer of activated crystalline gate material may have a doping level of 10²⁰ ions/cm³ or higher, preferably 5×10²⁰ ions/cm³ or higher.

The doping implant in the activated gate material may have an abruptness of 2 nm or more, preferably 1.5 nm or more, most preferred about 1 nm. Such high abruptness gives a significant improvement on the gate depletion, a problem in prior art devices, and may delay the need for metal gate introduction.

In a semiconductor device according to the present invention, the second layer of gate material may consist of amorphous gate material or of polycrystalline gate material. The grain size in the second layer may be below 40 nm, preferably below 30 nm. The first layer may be crystalline or very fine-grained, with grains below 5 nm. This clearly differs from prior art devices, where the grain size is above 30-40 nm.

A gate insulator may be provided between the semiconductor substrate and the gate electrode.

The device may be a transistor.

A solution is thus offered by the present invention for excellent activation of ion implanted dopants in a semiconductor material e.g. forming a gate, up to high doping levels, for both NMOS and PMOS, with no problems regarding gate material grain structure, for example polysilicon grain structure. With high doping levels is meant doping levels of 10²⁰ ions/cm³ or higher, preferably 10²¹ ions/cm³ or higher.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

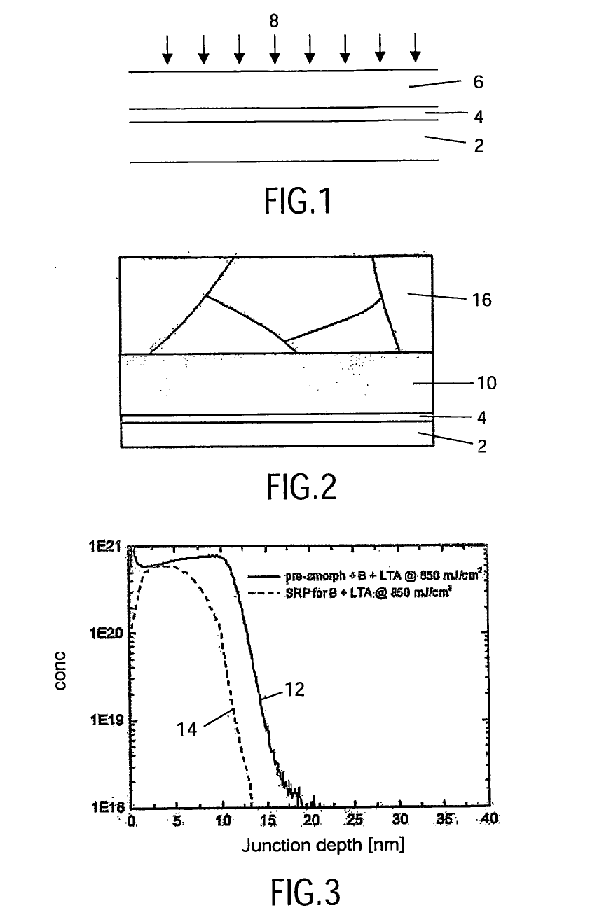

FIG. 1 is a schematic cross-section of a semiconductor substrate onto which a stack of a gate insulating film, and a first layer of gate material have been formed.

FIG. 2 is a schematic cross-section of a semiconductor substrate onto which a stack of a gate insulating film, a first layer of gate material and a second layer of gate material have been formed.

FIG. 3 is a graph of concentration in function of junction depth, showing SIMS and SRP profiles for a B 0.5 keV, 10¹⁵ implant laser thermal annealed at 850 mJ/cm². In the different figures, the same reference figures refer to the same or analogous elements.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

According to the present invention, in a first step, a substrate 2 is provided, as illustrated in FIG. 1. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. In the following processing will mainly be described with reference to silicon processing but the skilled person will appreciate that the present invention may be implemented based on other semiconductor material systems and that the skilled person can select suitable materials as equivalents of the dielectric and conductive materials described below.

As shown in FIG. 1, on top of the substrate 2, e.g. a silicon substrate, an insulating layer, for example a gate oxide layer 4, e.g. comprising silicon dioxide, is formed, for example by thermally growing it in an oxygen-steam ambient, at a temperature between about 600 to 1000° C., to a thickness between about 1 (or less) to 15 nm. Alternatively for example Rapid Thermal Oxidation (RTO) with in-situ steam generation (ISSG) can be used to obtain the gate oxide layer 4 or any other suitable method.

On top of the gate insulating layer or gate oxide layer 4, a 10 nm to 40 nm, preferably 20 nm to 30 nm, layer 6 of amorphous gate material, i.e. non-crystalline gate material, for example amorphous silicon is deposited. This deposition may be done by chemical vapor deposition (CVD). As a source gas, a gas mixture of silane (SiH₄) and hydrogen may be used. A flow rate of silane may be 0.5 slm (standard liters per minute), and a film deposition temperature may be 550° C. As no large grain polycrystalline structure is used at the interface with the gate insulator 4, a perfect interface is obtained.

Subsequently, dopants 8 are implanted ultra-shallow, i.e. just below the surface exposed to implantation, in the amorphous layer 6. These dopants 8 can be of a first type, e.g. p-type impurities such as boron (B), fluorine (F), B and F co-implants such as boron difluoride (BF₂), nitride (N), indium (In), chlorine (Cl), N and F co-implants, In and F co-implants or Cl and F co-implants for PMOS. An F-implant, if properly tuned, can give better abruptness of the dopant profile than any of the other implants. The dopants 8 can be of a second type, e.g. arsenic (As), phosphorus (P), antimony (Sb) or combinations thereof for NMOS. During implantation, semiconductor wafers, such as silicon wafers for example, are bombarded by a beam of electrically charged ions, called dopants. Implantation changes the properties of the material the dopants are implanted in, to achieve a particular electrical performance. The dopants are accelerated to an energy that will permit them to penetrate, i.e. implant, the wafers to a desired depth. Dopant concentration or dose is determined by controlling the number of ions in the beam and the number of times the wafer passes through the ion beam. The beam energy determines the depth at which the dopant will be placed. Typical doses and energies for implanting these doses are given hereinafter. In other embodiments also other intensities and energies may be used.
for B: 5×10¹⁴-2×10¹⁵ atoms/cm³ at 0.2-0.5 keV
for F: 10¹⁵ atoms/cm³ at 3-6 keV
for As: 5×10¹⁴-2×10¹⁵ atoms/cm³ at 1-2 keV
for Sb: 3×10¹⁴-3×10¹⁵ atoms/cm³ at 5-10 keV
   The amorphous layer 6 ensures that no channeling takes place. Channeling is an effect occurring during implantation of ions into crystalline solids. An implanted specie may enter an open channel in a crystal lattice as a result of which it may penetrate through the solid deeper than other implanted species which are subject to collisions with atoms in the lattice. The fact of having no channeling results in a limited tail in the dopant profile, i.e. the dopants are almost all present at the same depth in the amorphous layer.

The dopant implantation is followed by an anneal step. The anneal step can be a low temperature anneal step, such as in solid phase epitaxy (SPE) at 550° C. for example, a high temperature anneal step, such as rapid thermal annealing with high ramp rates (RTA) or flash rapid thermal annealing (fRTA), typically at between 1000° C. and 1300° C., or an anneal step above melting temperature, such as in laser thermal annealing (LTA). If properly tuned, the anneal step can give very abrupt dopant profiles, at a correct position, with a high level of activation. This results in a highly activated first gate material layer 10, as shown in FIG. 2.

FIG. 3 shows graphs of concentration in function of junction depth for an example of a 20 nm highly activated first gate material layer with B implant and an LTA annealing step. A dose of 10¹⁵ atoms/cm² of B is implanted with an energy of 0.5 keV in the layer of amorphous silicon. LTA is carried out at 850 mJ/cm², using an XeCl Eximer laser with wavelength λ=308 nm. The dotted line graph 14 indicates the Scanning Resistance Profile (SRP) which gives the active dopant concentration profile, the continuous line graph 12 is the Secondary Ion Mass Spectrometry (SIMS) profile, which is the dopants chemical concentration. It can be seen from the SIMS profile 12 that the abruptness of the doping profile reaches 1.8 nm/decade. The abruptness of the doping profile is important to avoid dopant implant in the insulator or in the channel. From the SRP profile 14 it can be seen that an activation level of 6×10²⁰ atoms/cm³ is reached.

The resulting first layer 10 of gate material, in the example given the first layer of silicon, is highly activated, crystalline, defect free, and acting almost as a metal electrode.

In a second step of the method according to the present invention, a second layer 16 of gate material, either amorphous gate material or polycrystalline gate material, for example amorphous silicon or polycrystalline silicon, is deposited. This second layer 16 of gate material has a thickness which depends on the technology. Typically, the thickness of this second layer is between 70 and 130 nm. FIG. 2 schematically shows the resulting structure.

From this point on, normal semiconductor processing flow is followed. In case of the example given, the second layer of polysilicon is doped and activated as in a conventional flow, during source/drain deep junction implant and anneal. These steps have to be low temperature steps, below 700° C., which in principle is the case for advanced devices, in order to prevent de-activation of the dopant atoms in the gate or broadening of the gate.

The method of the present invention, as described above, results in a very high level of dopant activation in the gate, so that the gate formed almost has the properties of a metal gate electrode.

A semiconductor device with a gate formed according to the method of the present invention has a very low gate depletion as well as improved ON-current with no increase of the OFF-state current.

The above method is easy to integrate in a CMOS flow.

It is to be understood that although preferred embodiments, specific constructions and configurations, as well as materials, have been discussed herein for devices according to the present invention, various changes or modifications in form and detail may be made without departing from the scope and spirit of this invention.

1. Method of forming a semiconductor device having a gate, comprising:
providing a first layer of amorphous gate material,
doping the first layer of amorphous gate material, thus forming a doped first layer of amorphous gate material,
thermally activating the doped first layer of gate material, thus forming an activated first layer of gate material, and
providing a second layer of gate material on top of the activated first layer of gate material.

2. A method according to claim 1, wherein the first and second layers of gate material are silicon-based.

3. A method according to claim 1, further comprising patterning the second layer of gate material and the activated first layer of gate material to form one or more gates on the substrate.

4. A method according to claim 1, wherein providing a first layer of amorphous gate material includes forming a layer of amorphous gate material having a thickness of about 10 nm to about 40 nm.

5. A method according to claim 1, wherein providing a second layer (16) of gate material includes forming a layer of gate material having a thickness of about 50 nm to about 150 nm.

6. An MIS type semiconductor device, comprising:
a semiconductor substrate,
a gate electrode formed on the gate insulating film and formed of gate material,
wherein the gate electrode comprises:
a first layer of activated crystalline gate material having a first side oriented towards a substrate and a second side oriented away from the substrate, the first layer of activated crystalline gate material having a doping level of 10¹⁹ ions/cm³ or higher, and
a second layer of gate material at the second side of the first layer of activated crystalline gate material.

7. A semiconductor device according to claim 6, wherein the first layer of activated crystalline gate material has a doping level of about 10²⁰ ions/cm³ or higher.

8. An MIS type semiconductor device according to claim 6, wherein the doping implant in the activated gate material has an abruptness of about 2 nm or more.

9. A semiconductor device according to claim 6, wherein the second layer of gate material consists of amorphous gate material.

10. A semiconductor device according to claim 6, wherein the second layer of gate material consists of polycrystalline gate material.

11. A semiconductor device according to claim 6, wherein the grain size in the second layer is below about 40 nm.

12. A semiconductor device according to claim 6, wherein the first layer is crystalline or very fine-grained, with grains below 5 nm.

13. A semiconductor device according to claim 6, wherein a gate insulator is provided between the semiconductor substrate and the gate electrode.

14. A semiconductor device according to claim 6, wherein the device is a transistor.

15. A method according to claim 1, wherein providing a first layer of amorphous gate material includes forming a layer of amorphous gate material having a thickness of about 20 nm to 30 nm.

16. A method according to claim 1, wherein providing a second layer of gate material includes forming a layer of gate material having a thickness of about 70 nm to about 130 nm.

17. A semiconductor device according to claim 6, wherein the first layer of activated crystalline gate material has a doping level of about 5×10²⁰ ions/cm³ or higher.

18. An MIS type semiconductor device according to claim 6, wherein the doping implant in the activated gate material has an abruptness of about 1.5 nm or more.

19. An MIS type semiconductor device according to claim 6, wherein the doping implant in the activated gate material has an abruptness of about 1 nm.

20. A semiconductor device according to claim 6, wherein the grain size in the second layer is below about 30 nm.
